(19) United States
(12) Patent Application Publication
(10) Pub. No.: US 2026/0282227 A1
(43) Pub. Date: Sep. 17, 2026

(54) ELECTRONIC COMPONENT EMBEDDED SUBSTRATE

(71) Applicant: SAMSUNG ELECTRO-MECHANICS CO., LTD., Suwon-si (KR)

(72) Inventor: Yong Wan Ji, Suwon-si (KR)

(73) Assignee: SAMSUNG ELECTRO-MECHANICS CO., LTD., Suwon-si (KR)

(21) Appl. No.: 19/178,964

(22) Filed: Apr. 15, 2025

(30) Foreign Application Priority Data
Nov. 29, 2024 (KR) 10-2024-0175651

(51) Int. Cl. H05K 1/11; H05K 1/03; H05K 1/185

(52) U.S. Cl. CPC H05K 1/115; H05K 1/0306; H05K 1/185; H05K 2201/09509

(57) ABSTRACT

An electronic component-embedded substrate includes a glass layer, a through-cavity penetrating between an upper surface and a lower surface of the glass layer, a blind member at least partially disposed within the through-cavity, an electronic component at least partially disposed within the through-cavity and attached to an upper surface of the blind member, and an insulating material covering respective at least portions of the glass layer, the blind member, and the electronic component, and filling at least a portion of the through-cavity.

### CROSS-REFERENCE TO RELATED APPLICATION(S)

This application claims the benefit of priority to Korean Patent Application No. 10-2024-0175651 filed on Nov. 29, 2024 in the Korean Intellectual Property Office, the disclosure of which is incorporated herein by reference in its entirety.

### TECHNICAL FIELD

The present disclosure relates to an electronic component embedded substrate.

### BACKGROUND

To respond to high-performance and miniaturization strategies of semiconductors, the level of miniaturization and high-density required for printed circuit boards is increasing. For example, to manufacture high-end products such as server boards, high-layer counts and large bodies are required. However, as the number of wiring layers increases and the size of the body increases, the board may become vulnerable to warpage. To prevent this problem, the use of a glass core is being considered. Meanwhile, a blind cavity may be processed to embed electronic components in the glass core, and the electronic components may be disposed therein. However, in the case of a blind cavity formed in a glass core, the bottom and wall surfaces may be uneven due to the effects of laser and etching. Therefore, problems may occur in the alignment ability of electronic components, deviation in the upper insulation thickness, via connectivity, and the like.

### SUMMARY

An aspect of the present disclosure is to provide an electronic component embedded substrate including a cavity for embedding electronic components in a glass layer, in which alignment capability of electronic components may be improved, freedom in the size of the electronic components may be improved, an influence of an angle of a cavity wall surface or uniformity of a bottom surface may be reduced, and a variation in an insulation thickness on an upper side of an electronic component and/or reliability of a via may be improved.

An aspect of the present disclosure is to form a through-cavity in a glass layer, dispose a separate blind member in a lower side of the through-cavity, and dispose electronic components on the blind member of the through-cavity to be embedded therein. The blind member may be, for example, but is not limited to, a glass block, a metal block, or a combination thereof.

According to an aspect of the present disclosure, an electronic component-embedded substrate includes a glass layer; a through-cavity penetrating between an upper surface and a lower surface of the glass layer; a blind member at least partially disposed within the through-cavity; an electronic component at least partially disposed within the through-cavity and attached to an upper surface of the blind member; and an insulating material covering at least portions of the glass layer, the blind member, and the electronic component, and filling at least a portion of the through-cavity.

According to an aspect of the present disclosure, an electronic component-embedded substrate includes a glass layer; a through-cavity penetrating between an upper surface and a lower surface of the glass layer; a glass block at least partially disposed in a lower side of the through-cavity; an electronic component at least partially disposed in an upper side of the through-cavity; and an insulating material covering respective at least portions of the glass layer, the glass block, and the electronic component, and filling at least a portion of the through-cavity.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a cross-sectional view schematically illustrating an example of an electronic component embedded substrate;

FIG. 3 is a schematic A-A’ cut plane view of the electronic component embedded substrate of FIG. 2;

FIG. 4 is a cross-sectional view schematically illustrating another example of an electronic component embedded substrate; and

FIG. 5 is a cross-sectional view schematically illustrating another example of an electronic component embedded substrate.

### DETAILED DESCRIPTION

Hereinafter, the present disclosure will be described with reference to the accompanying drawings. The shapes and sizes of elements in the drawings may be exaggerated or reduced for clearer description.

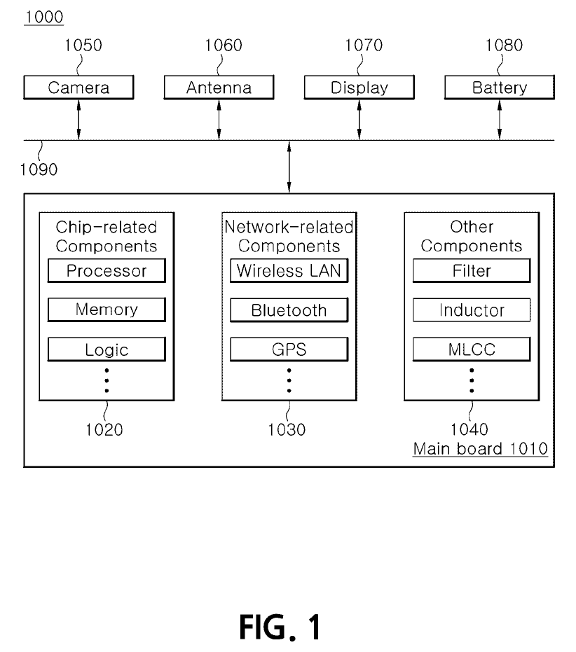

FIG. 1 is a block diagram schematically illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to other electronic components to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related electronic components. In addition, the chip related components 1020 may also be combined with each other. The chip related component 1020 may be in the form of a package including the aforementioned chip or electronic component.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access + (HSPA+), high speed downlink packet access + (HSDPA+), high speed uplink packet access + (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive elements in the form of chip components used for various other purposes, and the like. In addition, other components 1040 may also be combined with the chip related components 1020 and/or the network related components 1030.

Depending on a type of the electronic device 1000, the electronic device 1000 may include other electronic components that may or may not be physically or electrically connected to the mainboard 1010. These other electronic components may include, for example, a camera module 1050, an antenna module 1060, a display device 1070, a battery 1080, and the like, but are not limited thereto. These other electronic components may be an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. In addition, these other electronic components may also include other electronic components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, a server, or the like. However, the electronic device 1000 is not limited thereto, but may be any other electronic device processing data.

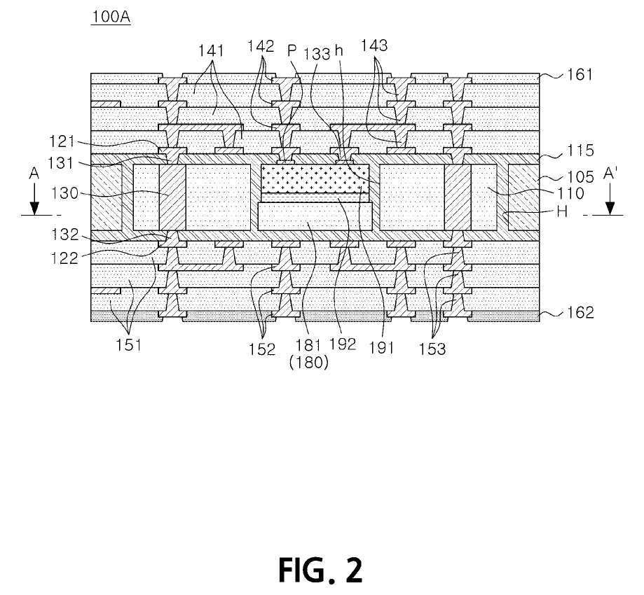

FIG. 2 is a cross-sectional view schematically illustrating an example of an electronic component-embedded substrate.

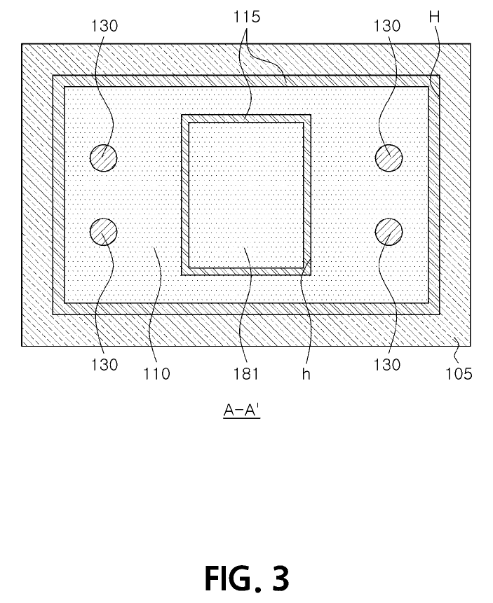

FIG. 3 is a schematic A-A’ cut plane view of the electronic component-embedded substrate of FIG. 2.

Referring to the drawings, an electronic component-embedded substrate 100A according to an example may include a glass layer 110, a through-cavity h penetrating between an upper surface and a lower surface of the glass layer 110, a blind member 180 at least partially disposed on a lower side within the through-cavity h, an electronic component 191 at least partially disposed on an upper side within the through-cavity h, and an insulating material 115 covering at least a portion of each of the glass layer 110, the blind member 180, and the electronic component 191 and filling at least a portion of the through-cavity h. The electronic component 191 may be attached to an upper surface of the blind member 180. For example, the electronic component 191 may have a connecting electrode P on the upper surface, and the lower surface of the electronic component 191 may be attached to the upper surface of the blind member 180 through the adhesive layer 192. The respective side surfaces of the blind member 180, the electronic component 191, and the adhesive layer 192 may be spaced apart from the wall surface of the through-cavity h. For example, the wall surface of the through-cavity h may continuously surround these respective side surfaces, but is not limited thereto. The insulating material 115 may fill at least a portion between the wall surface of the through-cavity h and these respective side surfaces.

In this way, in an electronic component-embedded substrate 100A according to an example, a through-cavity h instead of a blind cavity is formed in the glass layer 110, and thus, the above-described problems that may occur during the blind cavity formation process may be prevented. At this time, a separate blind member 180 may be disposed in the lower side of the through-cavity h, and thus, a structure similar to a blind cavity may be implemented. For example, the blind member 180 may provide a bottom surface on the lower side of the through-cavity h. Therefore, the shortcomings of the blind cavity structure may be supplemented and the advantages may be secured. For example, the alignment ability of the electronic component 191 may be improved, the degree of freedom in the size of the electronic component 191 may be improved, the influence of the angle of the wall surface of the through-cavity h or the uniformity of the bottom surface may be reduced, the thickness deviation of the area of the insulating material 115 disposed on the upper side of the electronic component 191 may be improved, and/or the reliability of the third connection via 133 formed in the area of the insulating material 115 disposed on the upper side of the electronic component 191 may be improved.

Referring to the drawings, an electronic component-embedded substrate 100A according to an example may further include a metal via 130 penetrating at least a portion between an upper surface and a lower surface of a glass layer 110, a first wiring layer 121 disposed on an upper surface of an insulating material 115, a second wiring layer 122 disposed on a lower surface of the insulating material 115, a first connection via 131 penetrating at least a portion of an upper side of the insulating material 115 and connecting at least a portion of the first wiring layer 121 to the metal via 130, a second connection via 132 penetrating at least a portion of a lower side of the insulating material 115 and connecting at least a portion of the second wiring layer 122 to the metal via 130, and a third connection via 133 penetrating at least another portion of an upper side of the insulating material 115 and connecting at least another portion of the first wiring layer 121 to a connecting electrode P. The metal via 130 may fill at least a portion of a through hole formed in the glass layer 110, for example, a Through Glass Via (TGV). The upper surface and the lower surface of the metal via 130 may have a step difference from the upper surface and the lower surface of the glass layer 110, but is not limited thereto. The first and second connection vias 131 and 132 may be directly connected to the metal via 130, respectively, and for example, may directly contact the metal via 130 without a separate pad or land. Therefore, the overall thickness of the substrate may be reduced, and the process difficulty may be reduced.

Referring to the drawing, an electronic component-embedded substrate 100A according to an example may further include a frame 105 and a penetration portion H penetrating between the upper surface and the lower surface of the frame 105. The glass layer 110 may be at least partially disposed within the penetration portion H. The insulating material 115 may further cover at least a portion of the frame 105 and further fill at least a portion of the penetration portion H. If necessary, at least a portion of the penetration portion h may also be filled with a separate filler. The frame 105 may include various materials having excellent rigidity. The frame 105 may be used as a jig during the process, and thus the process may be performed at the panel level through the frame 105, and the process warpage may be easily controlled. In addition, the frame 105 may remain in the final unit after singulation, and in this case, the warpage control of the final unit may be more advantageous.

Referring to the drawing, an electronic component-embedded substrate 100A according to an example may further include a plurality of first build-up insulation layers 141 disposed on an upper surface of an insulating material 115, a plurality of first build-up wiring layers 142 disposed on or within the plurality of first build-up insulation layers 141, a plurality of first build-up via layers 143 disposed on or within the plurality of first build-up insulation layers 141, a plurality of second build-up insulation layers 151 disposed on a lower surface of the insulating material 115, a plurality of second build-up wiring layers 152 respectively disposed on or within the plurality of second build-up insulation layers 151, and a plurality of second build-up via layers 153 respectively disposed within the plurality of second build-up insulation layers 151. In addition, the electronic component-embedded substrate 100A according to an embodiment may further include a first passivation layer 161 disposed on the plurality of first build-up insulation layers 141 and having a plurality of first openings that respectively expose at least portions of an uppermost first build-up wiring layer among the plurality of first build-up wiring layers 142, and a second passivation layer 162 disposed on the plurality of second build-up insulation layers 151 and having a plurality of second openings that respectively expose at least portions of a lowermost second build-up wiring layer among the plurality of second build-up wiring layers 152. For example, the electronic component-embedded substrate 100A according to an example may include a glass layer 110 as a core layer, and a build-up layer and the like formed on one side or both sides of the core layer, and therefore, may be easily utilized as a package substrate, an interposer substrate, or the like. In addition, the electronic component-embedded substrate 100A may be easily applied to other various types and/or various forms of printed circuit boards.

Hereinafter, components of an electronic component-embedded substrate 100A according to an example will be described in more detail with reference to the drawings.

The frame 105 may include an organic insulating material. The organic insulating material may include a thermosetting resin such as an epoxy resin, a thermoplastic resin such as a polyimide, or a resin together with an inorganic filler, an organic filler, and/or glass fiber (glass fiber, glass cloth, glass fabric). For example, the organic insulating material may include, but is not limited to, Copper Clad Laminate (CCL) or Unclad CCL, and may also include other organic or inorganic materials having excellent rigidity. The penetration portion H may penetrate between the upper and lower surfaces of the frame 105. The penetration portion H may continuously surround the side surface of the glass layer 110, but is not limited thereto.

The glass layer 110 may include glass, which is an amorphous solid. Glass may include, for example, pure silicon dioxide (about 100% SiO₂), soda lime glass, borosilicate glass, alumino-silicate glass, or the like. However, the present disclosure is not limited thereto, and alternative glass materials such as fluorine glass, phosphate glass, chalcogen glass, or the like may also be used as materials. Additionally, other additives may be further included to form glass with specific physical properties. These additives include calcium carbonate (for example, lime) and sodium carbonate (for example, soda), as well as magnesium, calcium, manganese, aluminum, lead, boron, iron, chromium, potassium, sulfur and antimony, and carbonates and/or oxides of these elements and other elements. Meanwhile, the glass layer 110 may be distinguished from an organic insulating material including glass fiber (Glass Fiber, Glass Cloth, Glass Fabric), for example, Copper Clad Laminate (CCL), Prepreg (PPG), or the like. The glass layer 110 may be, for example, in the form of a glass plate. The through-cavity h may penetrate between the upper and lower surfaces of the glass layer 110. The through-cavity h may continuously surround the side surfaces of the electronic component 191, the adhesive layer 192, and the blind member 180.

The insulating material 115 may include an organic insulating material. The organic insulating material may include a thermosetting resin such as an epoxy resin, a thermoplastic resin such as a polyimide, or an inorganic filler, an organic filler, and/or glass fiber (Glass Fiber, Glass Cloth, Glass Fabric) together with the resin. For example, the organic insulating material may include, but is not limited to, Prepreg (PPG), Ajinomoto Build-up Film (ABF), Photo Imageable Dielectric (PID), or the like. The insulating material 115 may be composed of a plurality of layers. The respective multiple layers may be integrated without a boundary therebetween, or the boundary between the layers may be distinct. The multiple layers may include substantially the same insulating material, but is not limited thereto, and may include different insulating materials.

The first and second wiring layers 121 and 122 may each include a metal. The metal may include copper (Cu), aluminum (Al), silver (Ag), tin (Sn), gold (Au), nickel (Ni), lead (Pb), titanium (Ti), and/or alloys thereof. For example, the first and second wiring layers 121 and 122 may each include chemical copper formed by electroless plating as a seed layer, and may include electrolytic copper formed by electrolytic plating based on the seed layer as a plating layer. The first and second wiring layers 121 and 122 may respectively perform various functions according to a design. For example, the first and second wiring layers 121 and 122 may each include a signal pattern, a power pattern, a ground pattern, and the like. These patterns may respectively have various shapes, such as a line, a trace, a plane, a land, a pad, and a land.

The metal via 130 may include a metal. The metal may include copper (Cu), aluminum (Al), silver (Ag), tin (Sn), gold (Au), nickel (Ni), lead (Pb), titanium (Ti), and/or alloys thereof. For example, the metal via 130 may include a titanium layer and a copper layer formed by sputtering, for example, sputtered titanium and sputtered copper, as seed layers, and may include electrolytic copper formed by electrolytic plating based on the titanium layer and the sputtered copper as a plating layer. If necessary, chemical copper formed by electroless plating may be further included as a seed layer. The metal via 130 may perform various functions depending on the design. For example, the metal via 130 may include a through-via for signal transmission, a through-via for power transmission, a through-via for ground transmission, and the like. The metal via 130 may be a field via in which a through-hole is filled with metal. The metal via 130 may have a substantially cylindrical shape, but may also have a substantially hourglass shape. The upper surface and the lower surface of the metal via 130 may be recessed inwardly relative to the upper surface and the lower surface of the glass layer 110, respectively, and thus the upper surface and the lower surface of the metal via 130 may have a step difference from the upper surface and the lower surface of the glass layer 110, respectively, but is not limited thereto. The metal via 130 may be plural.

The first to third connection vias 131, 132 and 133 may each include a metal. The metal may include copper (Cu), aluminum (Al), silver (Ag), tin (Sn), gold (Au), nickel (Ni), lead (Pb), titanium (Ti), and/or alloys thereof. For example, the first to third connection vias 131, 132 and 133 may each include chemical copper formed by electroless plating as a seed layer, and may include electrolytic copper formed by electrolytic plating as a plating layer based on the chemical copper. The first to third connection vias 131, 132 and 133 may respectively perform various functions according to a design. For example, the first to third connection vias 131, 132 and 133 may each include a connection via for signal transmission, a connection via for power transmission, a connection via for ground transmission, and the like. The first to third connection vias 131, 132 and 133 may each include a filled via in which at least a portion of a via hole is filled with metal, but may also include a conformal via in which metal is disposed along a wall surface of a via hole. The first to third connection vias 131, 132 and 133 may each have a substantially tapered shape. The first and second connection vias 131 and 132 may be directly connected to the upper and lower surfaces of the metal vias 130, respectively, and for example, may be in direct contact therewith. When there are a plurality of metal vias 130, the first and second connection vias 131 and 132 may also be a plurality correspondingly. When there are a plurality of connecting electrodes P, the third connection vias 133 may also be a plurality correspondingly.

Each of the plurality of first and second build-up insulation layers 141 and 151 may include an organic insulating material. The organic insulating material may include a thermosetting resin such as an epoxy resin, a thermoplastic resin such as a polyimide, or a resin together with an inorganic filler, an organic filler, and/or glass fiber (glass cloth, glass fabric). For example, the organic insulating material may include, but is not limited to, Prepreg (PPG), Ajinomoto Build-up Film (ABF), Photoimageable Dielectric (PID ), or the like. The plurality of respective layers of the plurality of first and second build-up insulation layers 141 and 151 may be integrated with each other without a boundary, or the boundary between the layers may be distinguished. In addition, the plurality of respective layers of the plurality of first and second build-up insulation layers 141 and 151 may include substantially the same insulating material, or may include different insulating materials. The plurality of first and second build-up insulation layers 141 and 151 may have the same number of layers, but this is not limited thereto, and the plurality of first build-up insulation layers 141 may have a relatively greater number of layers. If necessary, the plurality of second build-up insulation layers 151 may be omitted.

The plurality of first and second build-up wiring layers 142 and 152 may each include a metal. The metal may include copper (Cu), aluminum (Al), silver (Ag), tin (Sn), gold (Au), nickel (Ni), lead (Pb), titanium (Ti), and/or alloys thereof. For example, the plurality of first and second build-up wiring layers 142 and 152 may each include chemical copper formed by electroless plating as a seed layer, and may include electrolytic copper formed by electrolytic plating as a plating layer based on the chemical copper. The plurality of first and second build-up wiring layers 142 and 152 may perform various functions according to the design. For example, the plurality of first and second build-up wiring layers 142 and 152 may include signal patterns, power patterns, ground patterns, and the like, respectively. These patterns may have various shapes such as lines, traces, planes, lands, pads, and lands, respectively. The plurality of first and second build-up wiring layers 142 and 152 may have the same number of layers, but the plurality of first build-up wiring layers 142 may have a relatively greater number of layers. When the plurality of second build-up insulation layers 151 are omitted, the plurality of second build-up wiring layers 152 may also be omitted.

The plurality of first and second build-up via layers 143 and 153 may each include metal. The metal may include copper (Cu), aluminum (Al), silver (Ag), tin (Sn), gold (Au), nickel (Ni), lead (Pb), titanium (Ti), and/or alloys thereof. For example, the plurality of first and second build-up via layers 143 and 153 may each include chemical copper formed by electroless plating as a seed layer, and may include electrolytic copper formed by electrolytic plating based on the chemical copper as a plating layer. The plurality of first and second build-up via layers 143 and 153 may respectively perform various functions according to a design. For example, the plurality of first and second build-up via layers 143 and 153 may each include a connection via for signal transmission, a connection via for power transmission, a connection via for ground transmission, and the like. Each of the plurality of first and second build-up via layers 143 and 153 may include a filled via in which at least a portion of a via hole is filled with metal, but may also include a conformal via in which metal is disposed along a wall surface of the via hole. Each of the plurality of first and second build-up via layers 143 and 153 may include a plurality of connection vias. A connection via included in each of the plurality of first build-up via layers 143 and a connection via included in each of the plurality of second build-up via layers 153 may have shapes that are substantially tapered in opposite directions. The plurality of first and second build-up via layers 143 and 153 may have the same number of layers, but the plurality of first build-up via layers 143 may have a relatively greater number of layers. If multiple second build-up insulation layers 151 are omitted, multiple second build-up via layers 153 may also be omitted.

The first and second passivation layers 161 and 162 may each include an organic insulating material. The organic insulating material may include a thermosetting resin such as an epoxy resin, a thermoplastic resin such as a polyimide, or a resin together with an inorganic filler and/or an organic filler. For example, the organic insulating material may be, but is not limited to, Ajinomoto Build-up Film (ABF), Photoimageable Dielectric (PID), Solder Resist (SR), or the like. The first and second passivation layers 161 and 162 may each be composed of a plurality of layers. The first and second passivation layers 161 and 162 may each have multiple openings, and the pattern exposed through each opening may be, but is not limited to, Solder Mask Defined (SMD) and/or Non Solder Mask Defined (NSMD) types.

The blind member 180 may be disposed in the through-cavity h to provide a bottom surface of the through-cavity h. The blind member 180 may have various shapes and sizes. The blind member 180 may have a wider width in cross section than each of the electronic component 191 and the adhesive layer 192, and may also have a wider area in a plane. The blind member 180 may be spaced apart from the wall surface of the through-cavity h. The blind member 180 may include various materials, and for example, in an example, may include the glass described above in the glass layer 110. For example, in an example, the blind member 180 may be a glass block 181. The glass block 181 may include substantially the same material as the glass layer 110, for example, substantially the same glass. Since the glass block 181 that provides the bottom surface to the glass layer 110 and the through-cavity h includes substantially the same material, the difference in thermal expansion coefficients may be reduced, which may thus be more advantageous for warpage control, and the like.

The electronic component 191 may be attached to the bottom surface of the glass block 181 in a face-up form. For example, the electronic component 191 may include a connecting electrode P for electrical connection, and the connecting electrode P may be disposed on the upper surface, for example, the front surface, of the electronic component 191. The connecting electrode P may include a conductive material, for example, a metal. The metal may include copper (Cu), aluminum (Al), silver (Ag), tin (Sn), gold (Au), nickel (Ni), lead (Pb), titanium (Ti), and/or alloys thereof. The connecting electrode P may include a pad and may further include a bump or a post disposed on the pad. There may be a plurality of connecting electrodes P. The lower surface, for example, the back surface, of the electronic component 191 may be attached to the upper surface of the glass block 181181 through an adhesive layer 192. At this time, a known adhesive film such as a Die Attach Film (DAF) may be used as the adhesive layer 192. The electronic component 191 may be thicker than the adhesive layer 192. Through this arrangement, the technical effects described above may be further enhanced. The electronic component 191 may include various types of active components and/or passive components. For example, the electronic component 191 may include, but is not limited to, various types of integrated circuit dies or semiconductor chips.

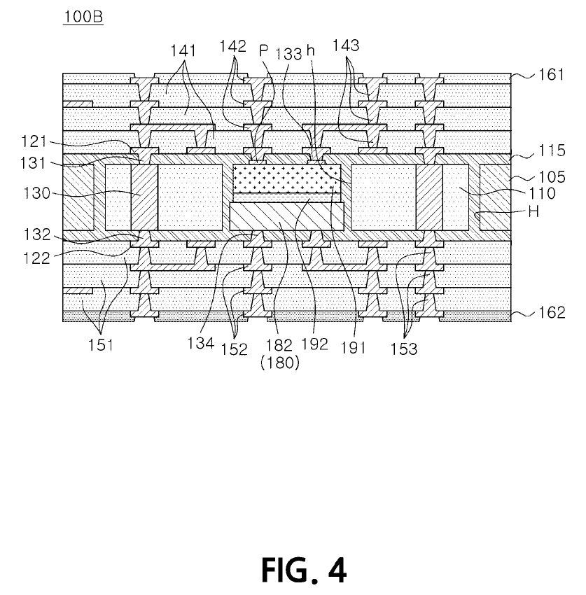

FIG. 4 is a cross-sectional view schematically illustrating another example of an electronic component-embedded substrate.

Referring to the drawing, an electronic component-embedded substrate 100B according to another example may include a metal block 182 as the blind member 180 in the electronic component-embedded substrate 100A according to the above-described example. In this case, the heat dissipation effect may be better. The metal block 182 may include copper (Cu), aluminum (Al), silver (Ag), tin (Sn), gold (Au), nickel (Ni), lead (Pb), titanium (Ti), and/or alloys thereof, and in detail, may include copper (Cu). Meanwhile, if necessary, the electronic component-embedded substrate 100B may further include a fourth connection via 134 penetrating at least another portion of the lower side of the insulating material 115 and connecting at least another portion of the second wiring layer 122 to the blind member 180, for example, the metal block 182. Therefore, heat may be more easily released to the lower portion of the substrate. The at least portion of the second wiring layer 122 connected to the metal block 182 may include a ground pattern and/or a power pattern, but is not limited thereto. As for a detailed description of the fourth connection via 134, the contents described in the first to third connection vias 131, 132 and 133 described above may be substantially identically applied. Other descriptions may be substantially identical to those described in the electronic component-embedded substrate 100A according to the above-described example.

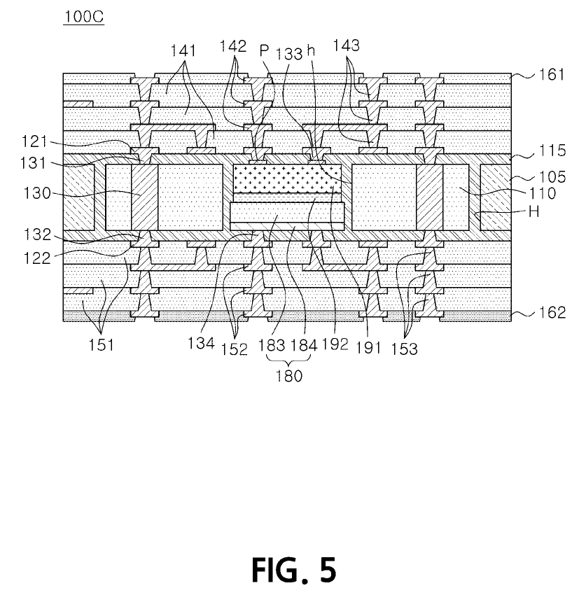

FIG. 5 is a cross-sectional view schematically illustrating another example of an electronic component-embedded substrate.

Referring to the drawing, in an electronic component-embedded substrate 100C according to another example, a blind member 180 includes a glass block 183 and a metal block 184 in the electronic component-embedded substrate 100A according to the above-described example. In this case, both a technical effect through the glass block 183 and a technical effect through the metal block 184 may be obtained. The metal block 184 may be attached to the lower surface of the glass block 183, and for example, may be directly connected to and in contact with the lower surface of the glass block 183. The metal block 184 may be thinner than the glass block 183. The detailed description of the glass block 183 and the metal block 184 may be substantially identically applied to the description of the glass block 181 and the metal block 182 described above. Meanwhile, if necessary, the electronic component-embedded substrate 100C may further include a fourth connection via 134 penetrating at least another portion of the lower side of the insulating material 115 and connecting at least another portion of the second wiring layer 122 to the blind member 180, for example, the metal block 184. The at least portion of the second wiring layer 122 connected to the metal block 184 may include a ground pattern and/or a power pattern, but is not limited thereto. As for a detailed description of the fourth connection via 134, the contents described in the first to third connection vias 131, 132 and 133 described above may be substantially applied in the same manner. Other descriptions may be substantially the same as those described in the electronic component-embedded substrate 100A according to the above-described example and the electronic component-embedded substrate 100B according to another example.

As set forth above, as an effect of the present disclosure, in an electronic component embedded substrate including a cavity for embedding electronic components in a glass layer, alignment capability of electronic components may be improved, freedom in the size of the electronic components may be improved, an influence on an angle of a cavity wall surface or uniformity of a bottom surface may be reduced, and a variation in an insulation thickness on an upper side of an electronic component and/or reliability of a via may be improved.

In the present disclosure, the expression “covering” may include not only a case of covering completely but also a case of covering at least partly, and may also include a case of covering indirectly but also a case of covering directly. In addition, the expression “filling” may include a case of filling at least partly but also a case of filling completely, and may also include a case of filling approximately. For example, it may include a case where some gaps or voids exist. Additionally, the expression of surrounding may include not only completely enclosing, but also partially enclosing and roughly enclosing. Additionally, exposing may include not only completely exposing, but also partially exposing, and exposure may mean exposing from burying the composition.

In the present disclosure, being disposed in a through-cavity or a penetration portion may include not only cases where the object is completely disposed in the through-cavity or penetration portion, but also cases where it is partially extended upward or downward in the cross section. For example, if it is disposed in the through-cavity or penetration portion on a plane, it may be judged in a broader sense.

In the present disclosure, it may be judged to include process errors, positional deviations, measurement errors, and the like that occur in the manufacturing process. For example, being disposed at substantially the same level may include not only cases where it is disposed at completely the same level, but also cases where it is disposed at approximately the same level. In addition, having substantially a specific shape may include not only cases where it has completely such a shape, but also cases where it has approximately such a shape. In addition, substantially the same insulating material may mean not only cases where it is completely the same insulating material, but also cases where it includes the same type of insulating material. Accordingly, the composition of the insulating material may be substantially the same, but the detailed composition ratio thereof may be slightly different.

In the present disclosure, the meaning of cross-section may mean a cross-sectional shape when the object is vertically cut, or a cross-sectional shape when the object is viewed from a side-view. The meaning of a plane may mean a plane shape when the object is horizontally cut, or a plane shape when the object is viewed from a top-view or bottom-view.

In the present disclosure, lower, lower portion, lower surface, and the like are used to mean a downward direction based on the cross section of the drawing for convenience, and upper, upper portion, upper surface, and the like are used to mean the opposite direction. However, this is to define the direction for convenience of description, and the scope of the claims is not particularly limited by the description of this direction, of course, and the concept of upper and lower may change at any time.

In the present disclosure, the meaning of being connected is a concept including not only being directly connected but also being indirectly connected by an adhesive layer or the like. In addition, the meaning of being electrically connected is a concept including both physically connected and nonconnected cases. In addition, expressions such as first, second and the like are used to distinguish one component from another, and do not limit the order and/or importance of the components. In some cases, without departing from the scope of rights, the first element may be named a second element, and similarly, the second element may be referred to as the first element.

In the present disclosure, thickness, width, length, depth, line width, spacing, pitch, separation distance, surface roughness, and the like may be respectively measured using a scanning microscope, an optical microscope or the like based on a cross section obtained by polishing or cutting an electronic component embedded substrate. The cut section may be a vertical section or a horizontal section, and each value may be measured based on the required cut section. For example, the width of the upper end and/or the lower end of the via may be measured on a cross-section cut along the central axis of the via. At this time, if the value is not constant, the value may be determined as the average value of the values measured at five random points.

The expression "an (one) example" used in the present disclosure does not mean the same embodiments, and is provided to emphasize and describe different unique characteristics. However, the examples presented above are not excluded from being implemented in combination with features of other examples. For example, even if a matter described in a specific example is not described in another example, it may be understood as a description related to another example, unless there is a description contrary to or contradictory to the matter in the other example.

Terms used in this disclosure are only used to describe an example, and are not intended to limit the disclosure. In this case, singular expressions include plural expressions unless the context clearly indicates otherwise.

While example embodiments have been shown and described above, it will be apparent to those skilled in the art that modifications and variations could be made without departing from the scope of the present invention as defined by the appended claims.

What is claimed is:

1. An electronic component-embedded substrate comprising:
a glass layer;
a through-cavity penetrating between an upper surface and a lower surface of the glass layer;
a blind member at least partially disposed within the through-cavity;
an electronic component at least partially disposed within the through-cavity and attached to an upper surface of the blind member; and
an insulating material covering respective at least portions of the glass layer, the blind member, and the electronic component, and filling at least a portion of the through-cavity.

2. The electronic component-embedded substrate of claim 1, wherein a side surface of each of the blind member and the electronic component is spaced apart from a wall surface of the through-cavity, and
the insulating material fills at least a portion between the side surface of each of the blind member and the electronic component and the wall surface of the through-cavity.

3. The electronic component-embedded substrate of claim 1, wherein the blind member includes a glass block.

4. The electronic component-embedded substrate of claim 3, wherein the glass block includes glass substantially identical to the glass layer.

5. The electronic component-embedded substrate of claim 1, wherein the blind member includes a metal block.

6. The electronic component-embedded substrate of claim 5, wherein the metal block includes copper.

7. The electronic component-embedded substrate of claim 1, wherein the blind member includes a glass block and a metal block connected to a lower surface of the glass block and having a thickness thinner than the glass block.

8. The electronic component-embedded substrate of claim 7, wherein the glass block includes glass substantially same as the glass layer, and
the metal block includes copper.

9. The electronic component-embedded substrate of claim 1, wherein the electronic component is provided with a connecting electrode disposed on an upper surface thereof, and
a lower surface of the electronic component is attached to the upper surface of the blind member through an adhesive layer.

10. The electronic component-embedded substrate of claim 9, further comprising:
a metal via penetrating at least a portion between the upper surface and the lower surface of the glass layer;
a first wiring layer disposed on an upper surface of the insulating material;
a second wiring layer disposed on a lower surface of the insulating material;
a first connection via penetrating at least a portion of an upper side of the insulating material and connecting at least a portion of the first wiring layer to the metal via;
a second connection via penetrating at least a portion of a lower side of the insulating material and connecting at least a portion of the second wiring layer to the metal via; and
a third connection via penetrating at least another portion of the upper side of the insulating material and connecting at least another portion of the first wiring layer to the connecting electrode.

11. The electronic component-embedded substrate of claim 10, wherein the first and second connection vias are respectively, directly connected to the metal via.

12. The electronic component-embedded substrate of claim 10, further comprising a fourth connection via penetrating at least another portion of the lower side of the insulating material and connecting at least another portion of the second wiring layer to the blind member, and
the blind member includes a metal block connected to the second connection via.

13. The electronic component-embedded substrate of claim 10, further comprising:
a frame; and
a penetration portion penetrating between an upper surface and a lower surface of the frame,
wherein the glass layer is at least partially disposed within the penetration portion, and
the insulating material further covers at least a portion of the frame and further fills at least a portion of the penetration portion.

14. The electronic component-embedded substrate of claim 10, further comprising:
a plurality of first build-up insulation layers disposed on the upper surface of the insulating material;
a plurality of first build-up wiring layers respectively disposed on or within the plurality of first build-up insulation layers;
a plurality of first build-up via layers respectively disposed within the plurality of first build-up insulation layers;
a plurality of second build-up insulation layers disposed on the lower surface of the insulating material;
a plurality of second build-up wiring layers respectively disposed on or within the plurality of second build-up insulation layers; and
a plurality of second build-up via layers respectively disposed within the plurality of second build-up insulation layers.

15. The electronic component-embedded substrate of claim 14, further comprising:
a first passivation layer disposed on the plurality of first build-up insulation layers and having a plurality of first openings respectively exposing at least a portion of an uppermost first build-up wiring layer among the plurality of first build-up wiring layers; and
a second passivation layer disposed on the plurality of second build-up insulation layers, and having a plurality of second openings respectively exposing at least a portion of a lowermost second build-up wiring layer among the plurality of second build-up wiring layers; further comprising.

16. An electronic component-embedded substrate comprising:
a glass layer;
a through-cavity penetrating between an upper surface and a lower surface of the glass layer;
a glass block at least partially disposed in a lower side of the through-cavity;
an electronic component at least partially disposed in an upper side of the through-cavity; and
an insulating material covering respective at least portions of the glass layer, the glass block, and the electronic component, and filling at least a portion of the through-cavity.

17. The electronic component-embedded substrate of claim 16, wherein the glass block includes glass substantially identical to the glass layer.

18. The electronic component-embedded substrate of claim 16, wherein an upper surface of the electronic component is provided with a connecting electrode, and
a lower surface of the electronic component is attached to the upper surface of the glass block through an adhesive layer.

19. The electronic component-embedded substrate of claim 18, wherein respective side surfaces of the electronic component, the adhesive layer, and the glass block are spaced apart from a wall surface of the through-cavity, and
the insulating material fills at least portions between the respective side surfaces of the electronic component, the adhesive layer, and the glass block and the wall surface of the through-cavity.

20. The electronic component-embedded substrate of claim 18, wherein the glass block has a wider width in cross section than the electronic component.
